(19) United States
(12) Patent Application Publication
(10) Pub. No.: US 2006/0236172 A1
(43) Pub. Date: Oct. 19, 2006

(54) Semiconductor device and method for testing the same

(75) Inventor: Kozo Okamoto, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/213,714

(22) Filed: Aug. 30, 2005

(30) Foreign Application Priority Data
Mar. 18, 2005 (JP) 2005-078973

(51) Int. Cl. G01R 31/28

(52) U.S. Cl. 714/724

(57) ABSTRACT

On a semiconductor wafer 10, semiconductor chip regions 12 including a semiconductor integrated circuit, a scribe line 14 formed adjacent to the semiconductor chip region 12, a test device 18 formed in the scribe line 14, electrically separated from the semiconductor circuit in the semiconductor chip region 12, for controlling a tester signal in testing the semiconductor integrated circuit are provided, and the semiconductor integrated circuit of the semiconductor chip region 12 and the test device 18 are electrically connected to each other through lines 38_{L}, 38_{R} provided in a probe card 16.

### CROSS-REFERENCE TO RELATED APPLICATIONS

This application is based upon and claims priority of Japanese Patent Application No. 2005-078973, filed on Mar. 18, 2005, the contents being incorporated herein by reference.

### BACKGROUND OF THE INVENTION

The present invention relates to a semiconductor device wherein semiconductor chips formed on a semiconductor wafer is tested in the wafer state, and a method for testing the same.

In the process of fabricating a semiconductor device, the test using a wafer prober including a tester and a probe card is performed (refer to, e.g., Japanese published unexamined patent application No. 2000-124278, Japanese published unexamined patent application No. Hei 4-320044 (1992) and Japanese published unexamined patent application No. 2002-176140). In the test using the wafer prober, tester signals are inputted to semiconductor chips on the wafer through the probe card, and based on output signals from the semiconductor chips, the semiconductor chips are judged to be normal or abnormal.

Recently, as the integration degree of semiconductor devices is increased, e.g., the increase of capacities of the semiconductor memories, the time required for the test of the semiconductor devices is on the increase, but the decrease of the time is required.

As means for shortening the time required for the test of semiconductor devices, as will be described below, the number of semiconductor chips to be simultaneously tested is increased.

First, a tester signal is divided on a probe card to be inputted to a plurality of semiconductor chips. FIG. 5 is a diagrammatic view illustrating the method for testing a semiconductor device, in which the tester signal is divided on the probe card.

As illustrated, on the probe card 100, a plurality of probe needles 104a, 104b are provided per one line 102 for a tester signal to be inputted to from the tester. In FIG. 5, two probe needles 104a, 104b are provided per one line 102.

In the test, a plurality of probe needles 104a, 104b are respectively brought into contact with pads 110 of discrete semiconductor chips 108 formed on a semiconductor wafer 106. A tester signal inputted from the tester to each line 102 is divided there to be inputted to the discrete semiconductor chips 106 from a plurality of probe needles 104a, 104b, respectively.

Thus, the tester signal is divided on the probe card, whereby the number of semiconductor chips to be simultaneously tested can be increased.

Furthermore, the division of tester signals is controlled by using test devices provided on the probe card. FIGS. 6A-6D are diagrammatic views illustrating a method for testing a semiconductor device by using a probe card including test devices for controlling the division of tester signals.

As illustrated in FIG. 6A, test devices 112 for controlling the division of test signals are provided on the probe card 100 between the probe needles 104a, 104b for the divided tester signals to be outputted to.

In the test, as in FIG. 5, a plurality of probe needles 104, 104b are respectively brought into contact with the pads 110 of discrete semiconductor chips 108 formed on a semiconductor wafer 106. Then, the test device 112 switches dividing a tester signal to input the respective divided tester signal to a plurality of the semiconductor chips 108 as illustrated in FIG. 6B to and from inputting a tester signal, undivided as it is to any one of the plural semiconductor chips 108 as illustrated in FIGS. 6C and 6D.

Test devices for dividing and compressing tester signals are fabricated in a semiconductor chip itself. FIG. 7 is a diagrammatic view illustrating a semiconductor chip with test devices for dividing and compressing tester signals incorporated in.

As illustrated, pads 118 for tester signal to be inputted to from probe needles 116 of a probe card are formed on the input side of the semiconductor chip 114. The test devices 120 for dividing the tester signals inputted to the pads 118 are connected to the pads 118. The test devices 120 are incorporated in the semiconductor chip 114. In FIG. 7, in the part circled by the dotted line on the input side of the semiconductor chip 114, the tester signal is indicated by the arrow to indicate the division of the tester signal by the test device 120.

On the output side of the semiconductor chip 114, pads 122 for output signal of the semiconductor chip 114 to be outputted from are formed. Test devices 124 for compressing output signals of the semiconductor chips 114 are connected to the pads 122. The test devices 124 are incorporated in the semiconductor chip 114. In FIG. 7, in the part circled by the dotted line on the output side of the semiconductor chip 114, an output signal is indicated by the arrow to indicate the compression of output signals by the test device 124. In the test, the probe needles 126 of the probe card are brought into contact with the pads 122, and the output signals are inputted to the tester through the probe card. In the tester, based on the inputted output signals of the semiconductor chip 114, whether the semiconductor chip 114 is normal or abnormal is judged.

However, the conventional method for testing a semiconductor device described above has the following disadvantages.

When a tester signal is divided on the probe card to simultaneously test a plurality of semiconductor chips, the semiconductor chips simultaneously tested are electrically connected to each other. Accordingly, when one of the semiconductor chips simultaneously tested is abnormal, the other semiconductor chips are often erroneously judged abnormal even when they are normal. This erroneous judgment results in the lower yield.

FIG. 8 is a view illustrating the erroneous judgment of the abnormality of semiconductor chips by the method for testing semiconductor chips, in which a test signal is divided on the above-described probe card. FIG. 8 illustrates an arrangement of semiconductor chips 108 formed on a semiconductor wafer. The numbers on the respective semiconductor chips 108 indicate the groups of the semiconductor chips simultaneously tested. The adjacent semiconductor chips 108 having the same numbers are simultaneously tested.

In FIG. 8, in the groups 1, 5, 8 and 9 enclosed by the dotted line ellipses, one of the semiconductor chips 108 are abnormal semiconductor chips 108_{NG}. In the actual test, in these groups, often the other semiconductor chips tested simultaneously with the abnormal semiconductor chips 108_{NG} are erroneously judged abnormal although the other semiconductor chips 108 are actually normal.

When the test is made with test devices provided on the probe card, it is often difficult to provide the test devices themselves on the probe card due to areas required for the test devices, temperature ranges ensuring the operation of the test devices, etc.

When test devices for dividing and compressing test signals are incorporated in the semiconductor chip, it is necessary to ensure regions for the test devices to be formed in, which are different from regions for the intrinsic circuits of the semiconductor chip to be formed in. This increases the area of the semiconductor chip.

### SUMMARY OF THE INVENTION

An object of the present invention is to provide a semiconductor device which realizes a highly efficient test of a semiconductor device with increase of the number of semiconductor chips to be simultaneously tested and highly reliable test of a semiconductor device, and a method for testing the same.

According to one aspect of the present invention, there is provided a semiconductor device comprising: a semiconductor chip region formed on a semiconductor wafer and including a semiconductor integrated circuit; a scribe region arranged adjacent to the semiconductor chip region; and a test device formed in the scribe region, electrically separated from the semiconductor integrated circuit, for controlling a test signal inputted in testing the semiconductor integrated circuit.

According to another aspect of the present invention, there is provided semiconductor device comprising: a first semiconductor chip region formed on a semiconductor wafer and including a semiconductor integrated circuit; a second semiconductor chip region formed on the semiconductor wafer and including a semiconductor integrated circuit; a scribe region arranged between the first semiconductor chip region and the second semiconductor chip region; and a test device formed in the scribe region, electrically separated from the semiconductor integrated circuit in the first semiconductor chip region and the semiconductor integrated circuit in the second semiconductor chip region, for controlling a test signal inputted in testing the semiconductor integrated circuit in the first semiconductor chip region and the semiconductor integrated circuit in the second semiconductor chip region.

According to further another aspect of the present invention, there is provided a semiconductor device comprising: a semiconductor chip region formed on a semiconductor wafer and including a semiconductor integrated circuit; a scribe region arranged adjacent to the semiconductor chip region; a test device for signal division formed in the scribe region, electrically separated from the semiconductor integrated circuit, for dividing a test signal inputted in testing the semiconductor integrated circuit; and a test device for signal compression formed in the scribe region, electrically separated from the semiconductor integrated circuit, for compressing output signals outputted from the semiconductor integrated circuit the test signal has been inputted to.

According to further another aspect of the present invention, there is provided a method for testing a semiconductor device comprising: a semiconductor chip region formed on a semiconductor wafer and including a semiconductor integrated circuit; a scribe region arranged adjacent to the semiconductor chip region; and a test device formed in the scribe region, electrically separated from the semiconductor integrated circuit, for controlling a test signal inputted in testing the semiconductor integrated circuit, the semiconductor integrated circuit and the test device being electrically connected to each other via an outside line, and the semiconductor integrated circuit being tested by using the test signal inputted from the test device to the semiconductor integrated circuit via the outside line.

According to further another aspect of the present invention, there is provided a method for testing a semiconductor device comprising: a first semiconductor chip region formed on a semiconductor wafer and including a semiconductor integrated circuit; a second semiconductor chip region formed on the semiconductor wafer and including a semiconductor integrated circuit; a scribe region arranged between the first semiconductor chip region and the second semiconductor chip region; and a test device formed in the scribe region, electrically separated from the semiconductor integrated circuit in the first semiconductor chip region and the semiconductor integrated circuit in the second semiconductor chip region, for controlling a test signal inputted in testing the semiconductor integrated circuit in the first semiconductor chip region and the semiconductor integrated circuit in the second semiconductor chip region, the semiconductor integrated circuit in the first semiconductor chip and the test device being electrically connected to each other, and the semiconductor integrated circuit in the second semiconductor chip and the test device being electrically connected to each other, and the semiconductor integrated circuit in the first semiconductor chip region and the semiconductor integrated circuit in the second semiconductor chip region being tested by using the test signal inputted from the test device to the semiconductor integrated circuit in the first semiconductor chip region and the semiconductor integrated circuit in the second semiconductor chip region.

According to the present invention, a test device for controlling a test signal is formed in a scribe region of a semiconductor wafer with a semiconductor chip region formed on, whereby the area of the semiconductor chip region can be small. Accordingly, a larger number of the semiconductor chip regions can be formed on the semiconductor wafer.

According to the present invention, test signal is divided by the tester device to be inputted to both semiconductor chip regions on both sides of the scribe region, whereby a larger number of the semiconductor chip regions can be simultaneously tested by the conventional tester without increasing the performance of the tester of the wafer prober. Thus, the time required to test a plurality of the semiconductor chip regions can be much shortened.

According to the present invention, test signal can be inputted to one alone of the semiconductor chip regions arranged on both sides of a scribe region, which permits the semiconductor chip regions to be tested independently of each other. Accordingly, the semiconductor chip regions never electrically influences each other in the test, which makes it possible to judge with high accuracy whether the semiconductor chip regions are normal or abnormal.

According to the present invention, the test device formed in the scribe region and the semiconductor chip regions are electrically connected to each other by no lines formed on the semiconductor wafer but electrically connected through the probe card, whereby the constitution, arrangement, etc. of the test device can be suitably altered without considering influences on the semiconductor chip region. When the semiconductor chip region is cleaved along the scribe region by dicing, no lines are exposed on the cleaved surfaces of the semiconductor chip region, and accordingly, the semiconductor chip cleaved in a piece is free from influences, such as the moisture resistance decrease, etc.

### BRIEF DESCRIPTION OF THE DRAWINGS

FIG. 1 is a diagrammatic view of the semiconductor wafer and the probe card used in the method for testing the semiconductor device according to a first embodiment of the present invention.

FIG. 2 is an enlarged diagrammatic view of semiconductor chip regions and a scribe line in the method for testing the semiconductor device according to the first embodiment.

FIG. 3 is a diagrammatic view of the test device of the semiconductor device according to a modification of the first embodiment of the present invention.

FIG. 4 is a diagrammatic view of the semiconductor device according to a second embodiment of the present invention.

FIG. 5 is a diagrammatic view illustrating a method for testing a semiconductor device in which a tester signal is divided on a probe card.

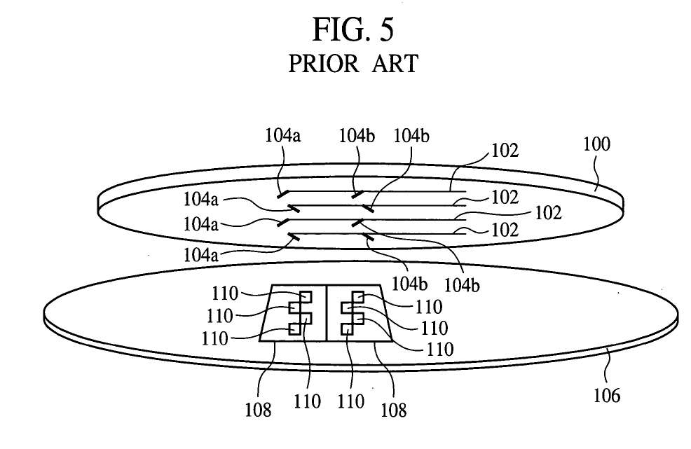

FIGS. 6A-6D are diagrammatic views illustrating a method for testing a semiconductor device in which a probe card with a test device for controlling the division of a tester signal is provided.

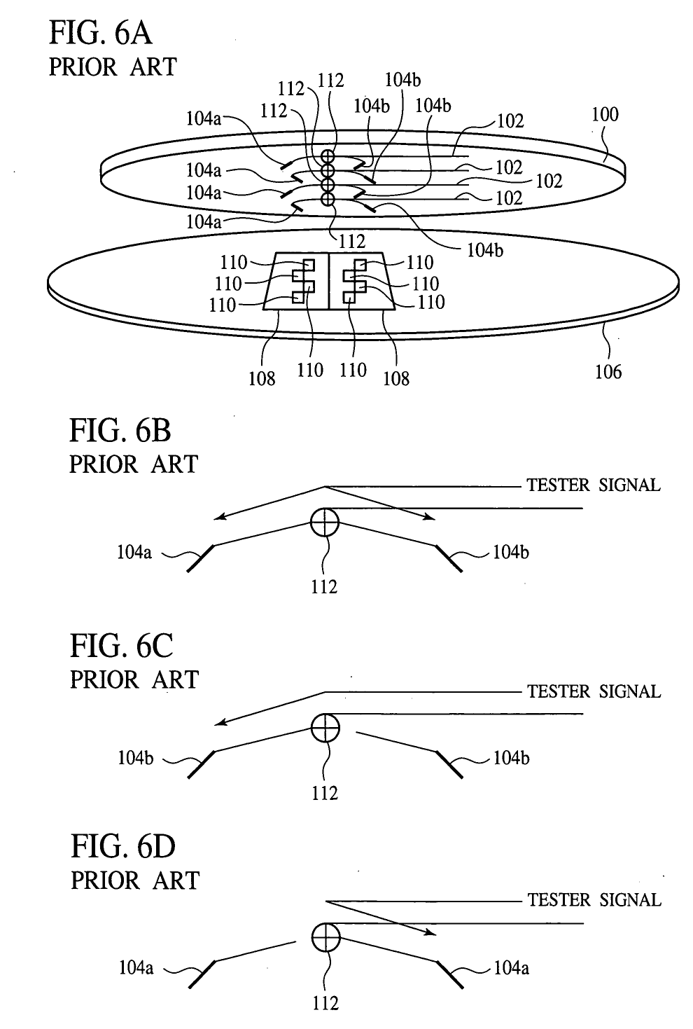

FIG. 7 is a diagrammatic view of semiconductor chip with test devices for dividing and compressing tester signals incorporated.

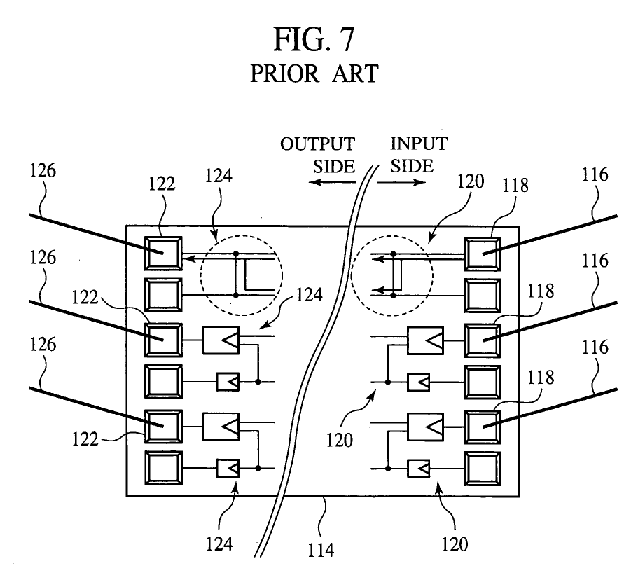

FIG. 8 is a view explaining the erroneous judgment as to whether semiconductor chips are normal or abnormal in the method for testing a semiconductor device in which a tester signal is divided on a probe card.

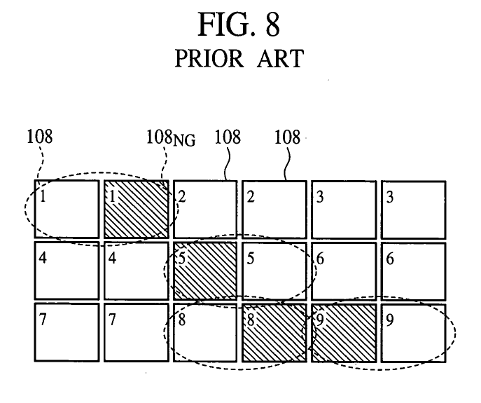

### DETAILED DESCRIPTION OF THE INVENTION

### A First Embodiment

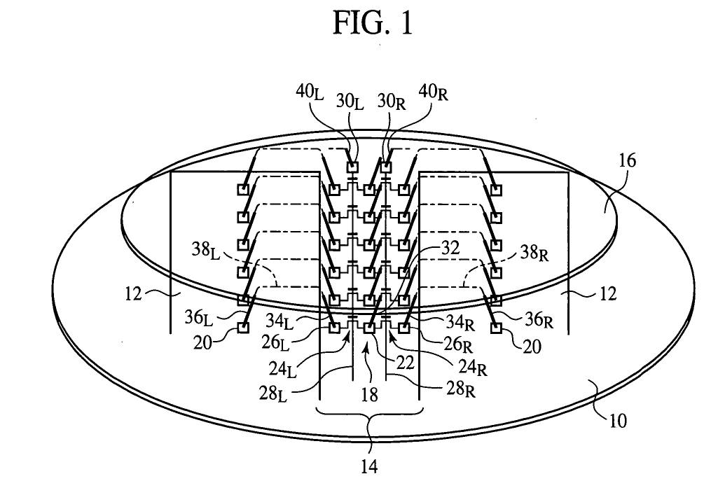

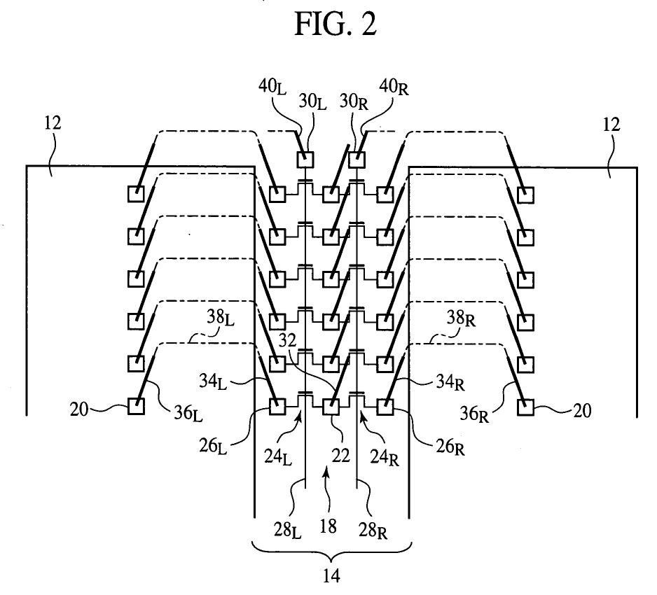

The semiconductor device and the method for testing the same according to a first embodiment of the present invention will be explained with reference to FIGS. 1 and 2. FIG. 1 is a diagrammatic view of the semiconductor wafer and the probe card used in the method for testing the semiconductor device according to the present embodiment. FIG. 2 is an enlarged diagrammatic view of the scribe line and the semiconductor chip regions adjacent to the scribe line in FIG. 1.

In the method for testing the semiconductor device according to the present embodiment, a wafer prober including a tester and a probe card is used to input tester signals to semiconductor chip regions on a wafer before dicing the semiconductor chip region into a semiconductor chip, and based on output signals from the semiconductor chip regions, the normality of the semiconductor chip regions is judged.

First, the semiconductor device according to the present embodiment, which is tested in the wafer state by the wafer prober, will be explained with reference to FIGS. 1 and 2.

As illustrated in FIG. 1, a plurality of semiconductor chip regions 12 are formed on a semiconductor wafer 10. In each semiconductor chip region 12, a prescribed semiconductor integrated circuit is formed. Between adjacent semiconductor chip regions 12, a scribe line 14 which is a cutting region for dicing the respective semiconductor chip regions 12 into semiconductor chips is provided. In the scribe line 14, test devices 18 for controlling tester signals inputted from the probe card 16 when the semiconductor chips 12 are tested are formed. In FIG. 1, for simplicity, two semiconductor chip regions 12 adjacent to each other with the scribe line 14 provided therebetween are illustrated.

The semiconductor chip region 12 including the semiconductor integrated circuit and the test device 18 are physically and electrically separated from each other on the semiconductor wafer 10, but as will be described later, both are arranged capable of being electrically connected through the probe card 16.

Pads 20 for tester signals to be inputted to are provided in the semiconductor chip regions 12 formed on the semiconductor wafer 10.

In the scribe line 14, a plurality of test devices 18 for dividing tester signals inputted from the probe card 16, etc. are formed, corresponding to the number of pads 20 in the semiconductor chip region 12.

The test device 18 comprises a semiconductor integrated circuit formed on the semiconductor wafer 10 and, as illustrated in FIGS. 1 and 2, includes a pad 22 for the tester signal to be inputted to, pairs of switching devices 24_{L}, 24_{R} which input the tester signal to the semiconductor chip region 12 or shut off the tester signal, and pads 26_{L}, 26_{R} connected to the output terminals of the switching devices 24_{L}, 24_{R}, for the tester signal to be outputted from. The switching devices 24_{L}, 24_{R} are formed of, e.g., MIS transistor.

The switching devices 24_{L}, 24_{R} of the test device 18 are respectively connected to signal lines 28_{L}, 28_{R} which turn on or off the switching devices 24_{L}, 24_{R}. The signal lines 28_{L}, 28_{R} are respectively connected to pads 30_{L}, 30_{R} formed in the scribe line 14, for switch signals for tuning on or off the switching devices 24_{L}, 24_{R} to be inputted to from the probe card 16.

Thus, the semiconductor device according to the present embodiment is constituted.

Next, the probe card 16 of the wafer prober used in the method for testing the semiconductor device according to the present embodiment will be explained with reference to FIGS. 1 and 2. In the following description, when it is necessary to discriminate the semiconductor chip regions located on the left and the right sides of the scribe line 14 from each other, the semiconductor chip region 12 on the left side will be called “the semiconductor chip region 12_{L}”, and the semiconductor chip region 12 on the right side will be called “the semiconductor chip region 12_{R}”

The probe card 16 has probe needles 32 which, in the test, contact the pads 22 of the test devices 18 to input tester signals.

On the probe card 16, probe needles 34_{L} which contact the pads 26_{L} of the test devices 18 in the test, and probe needles 36_{L} which contact the pads 20 of the semiconductor chip region 12_{L} in the test are provided. The probe needles 34_{L} and the probe needles 36_{L} are electrically connected to each other by lines 38_{L} provided on the probe card 16. In the test, the semiconductor chip region 12_{L} including the semiconductor integrated circuit, and the test device 18 are electrically connected with each other by the probe card 16, that is, by the probe needles 34_{L}, 36_{L} and the line 38_{L} electrically interconnecting the probe needles 34_{L} and the probe needles 36_{L}. Thus, a tester signal can be inputted from the test device 18 to the semiconductor integrated circuit in the semiconductor chip region 12_{L}.

On the probe card 16, probe needles 34_{R} which contact the pads 26_{R} of the test devices 18 in the test, and probe needles 36_{R} which contact the pads 20 of the semiconductor chip region 12_{R} in the test are provided. The probe needles 34_{R} and the probe needles 36_{R} are electrically connected to each other by lines 38_{R} provided on the probe card 16. In the test, the semiconductor chip region 12_{R} including the semiconductor integrated circuit, and the test device 18 are electrically connected with each other by the probe card 16, that is, by the probe needles 34_{R}, 36_{R} and the line 38_{R} electrically interconnecting the probe needles 34_{R} and the probe needles 36_{R}. Thus, a tester signal can be inputted from the test device 18 to the semiconductor integrated circuit in the semiconductor chip region 12_{R}.

Furthermore, on the probe card 16, probe needles 40_{L}, 40_{R} which, in the test, electrically contact the pads 30_{L}, 30_{R} connected to the signal lines 28_{L}, 28_{R} to input switch signal for turning on or off the switching devices 24_{L}, 24_{R} are provided.

In the test, the switching devices 24_{L}, 24_{R} are turned on or off, based on the switch signals inputted from the signal lines 38_{L}, 38_{R} to the switching devices 24_{L}, 24_{R}. The tester signal inputted to the test device 18 is thus divided to input the tester signal on both of the semiconductor chip region 12_{L} and the semiconductor chip region 12_{R} arranged on both sides of the scribe line 14 or to input the tester signal inputted to the test device 18 to either of the semiconductor chip region 12_{L} and the semiconductor chip region 12_{R} arranged on both sides of the scribe line 14.

Specifically, the switching devices 24_{L}, 24_{R} are both turned on to thereby divide the tester signal inputted to the test device 18 to input the test signal to both of the semiconductor chip regions 12_{L}, 12_{R}.

The switching device 24_{L} is turned on and the switching device 24_{R} is turned off to thereby input no tester signal to the semiconductor chip region 12_{R} of the semiconductor chip regions 12_{L}, 12_{R} but input the tester signal to the semiconductor chip region 12_{L} alone.

The switching device 24_{R} is turned on and the switching device 24_{L} is turned off to thereby input no tester signal to the semiconductor chip region 12_{L} of the semiconductor chip regions 12_{L}, 12_{R} but input the tester signal to the semiconductor chip region 12_{R} alone.

As described above, the semiconductor device according to the present embodiment, on which the test using the wafer prober is made, is characterized in that the test device 18 for controlling the tester signal to be inputted in testing semiconductor integrated circuit in the semiconductor chip region 12 is formed in the scribe line 14 of the semiconductor wafer 10 with the semiconductor chip regions 12 formed on.

The test device 18 is formed not in the semiconductor chip region 12 but in the scribe line 14, which decreased the area of the semiconductor chip region 12. Accordingly, a larger number of the semiconductor chip regions 12 can be formed on the semiconductor wafer 10.

The semiconductor device according to the present embodiment is characterized also in that the switching devices 24_{L}, 24_{R} are turned on or off to thereby divide the tester signal inputted to the test device 18 to input the tester signal to both the semiconductor chip region 12_{L} and the semiconductor chip region 12_{R} arranged on both sides of the scribed line 14 or input the tester signal inputted to the test device 18 to either of the semiconductor chip regions 12_{L}, 12_{R} arranged on both side of the scribe line 14.

The tester signal is divided by the test device 18 to input the tester signal to both the semiconductor chip region 12_{L} and the semiconductor chip region 12_{R}, which makes it possible to simultaneously test a larger number of semiconductor chip regions 12 by using the conventional tester without increasing the performance of the tester of the wafer prober. Thus, the semiconductor device can decrease the time required to test a plurality of semiconductor chip regions 12 and make the test efficient.

The tester signal can be inputted to either of the semiconductor chip regions 12_{L}, 12_{R} arranged on both sides of the scribe line 14, which makes it possible to test the semiconductor chip regions 12_{L}, 12_{R} independently of each other. Accordingly, in the test, the semiconductor chip region 12 can be judged with high accuracy as to whether it is normal or abnormal, without the semiconductor chip regions 12_{L}, 12_{R} electrically affecting each other.

Furthermore, the semiconductor device according to the present embodiment is characterized also in that the test device 18 formed in the scribe line 14 and the semiconductor chip region 12 are not electrically connected to each other by lines formed on the semiconductor wafer 10, but are electrically connected to each other through the probe card 16.

As described above, the semiconductor chip region 12 including the semiconductor integrated circuit, and the test device 18 are physically and electrically separated from each other on the semiconductor wafer 10, which permits the structure, arrangement, etc. of the test device 18 to be suitably altered without considering influence to the semiconductor chip region 12.

No line electrically connecting the test device 18 and the semiconductor chip region 12 to each other is present on the semiconductor wafer 10. Accordingly, even when the semiconductor chip region 12 is cleaved into a piece along the scribe line 14 by dicing, no line is exposed on the cleaved surfaces of the semiconductor chip region 12. Accordingly, the test device 18, which is formed in the scribed line 14, never gives influences, such as the moisture resistance decrease, etc., on the cleaved semiconductor chip.

Next, the method for testing the semiconductor device according to the present embodiment will be explained with reference to FIGS. 1 and 2.

First, the semiconductor wafer 10 with the test device 18 formed in the scribe line 14, and the probe card 16 are aligned with each other to contact the prescribed pads on the semiconductor wafer 10 with the prescribed probe needles of the probe card 16 as illustrated in FIGS. 1 and 2. That is, the pad 22 of the test device 18 is contacted with the probe needle 32. The pad 26_{L} of the test device 18 is contacted with the probe needle 34_{L}, and the pad 20 of the semiconductor chip region 12_{L} is contacted with the probe needle 36_{L}, whereby the pad 26_{L} of the test device 18 and the pad 20 of the semiconductor chip region 12_{L} are electrically contacted with each other. The pad 26_{R} of the test device 18 is contacted with the probe needle 34_{R} and the pad 20 of the semiconductor chip region 12_{R} is contacted with the probe needle 36_{R}, whereby the pad 26_{R} of the test device 18 and the pad 20 of the semiconductor chip region 12_{R} are electrically contacted with each other. The pad 30_{L} is contacted with the probe needle 40_{L}, and the pad 30_{R} is contacted with the probe needle 40_{R}.

Then, a tester signal generated by the tester of the wafer prober is inputted to the pad 22 of the test device 18 from the probe needle 32 of the probe card 16.

The tester signal inputted to the pad 22 of the test device 18 is inputted to the semiconductor chip region 12 through the test device 18 as follows in accordance with the case that the semiconductor chip regions 12_{L}, 12_{R} on both sides of the scribe line 14 are simultaneously tested and the case that either of the semiconductor chip regions 12_{L}, 12_{R} is tested.

In the case that the semiconductor chip regions 12_{L}, 12_{R} on both sides of the scribe line 14 are simultaneously tested, a switch signal generated by the tester, for turning on the switch device 24_{L} is inputted from the probe needle 40_{L} to the pad 30_{L} connected to the signal lines 28_{L}. The switch signal is inputted to the switching device 24_{L} from the signal line 28_{L}, and the switching device 24_{L} is turned on. Concurrently therewith, a switch signal generated by the tester, for turning on the switching device 24_{R} is inputted to the pad 30_{R} connected to the signal line 28_{R}. The switch signal is inputted to the switching device 24_{R} from the signal line 28_{R}, and the switching device 24_{R} is also turned on.

Both the switching devices 24_{L}, 24_{R} are thus turned on, whereby the tester signal inputted to the pad 22 of the test device 18 is outputted from the respective pads 26_{L}, 26_{R} connected to the output terminals of the switching devices 24_{L}, 24_{R}.

The tester signal outputted from the pad 26_{L} is inputted to the semiconductor integrated circuit in the semiconductor chip region 12_{L} through the probe needle 34_{L}, the line 38_{L} and probe needle 36_{L}. In the same way, the tester signal outputted from the pad 26_{R} is inputted to the semiconductor integrated circuit in the semiconductor chip region 12_{R} through the probe needle 34_{R}, the line 38_{R} and the probe needle 36_{R}.

Thus, the tester signal is simultaneously inputted respectively to the semiconductor chip regions 12_{L}, 12_{R} on both sides of the scribe line 14.

Then, based on the output signals outputted from the semiconductor integrated circuits in the semiconductor chip regions 12_{L}, 12_{R} to which the tester signal have been inputted to, it is judged whether the semiconductor integrated circuits in the semiconductor chip regions 12_{L}, 12_{R} are normal or abnormal.

In the case that of the semiconductor chip regions 12_{L}, 12_{R} positioned on both sides of the scribe line 14, the semiconductor chip region 12_{L} alone is tested, a switch signal generated by the tester, for turning on the switching device 24_{L} is inputted from the probe needle 40_{L} to the pad 30_{L} connected to the signal lines 28L. The switch signal is inputted to the switching device 24_{L} from the signal line 28_{L}, and the switching device 24_{L} is turned on. On the other hand, a switch signal generated by the tester, for turning off the switching device 24_{R} is inputted from the probe needle 40_{R} to the pad 30_{R} connected to the signal line 28_{R}. The switch signal is inputted from the signal line 28_{R} to the switching device 24_{R}, and the switching device 24_{R} is turned off.

The switching device 24_{L} is thus turned on, and the tester signal inputted to the pad 22 of the test device 18 is outputted to the pad 26_{L} connected to the output terminal of the switching devices 24_{L}. On the other hand, the switching device 24_{R} is turned off, and the tester signal from the pad 26_{R} is not outputted.

The tester signal outputted from the pad 26_{L} is inputted to the semiconductor integrated circuit in the semiconductor chip region 12_{L} through the probe needle 34_{L}, the line 38_{L} and the probe needle 36_{L}. On the other hand, the tester signal from the pad 26_{R}, which has not been outputted, is not inputted to the semiconductor integrated circuit in the semiconductor chip region 12_{R}. Thus, the tester signal is inputted to the semiconductor chip region 12_{L} alone of the semiconductor chip regions 12_{L}, 12_{R} on both sides of the scribe line 14.

Then, based on the output signal from the semiconductor integrated circuit in the semiconductor chip region 12_{L}, to which the tester signal has been inputted, it is judged whether the semiconductor integrated circuit in the semiconductor chip region 12_{L} is normal or abnormal.

In the case that the semiconductor chip region 12_{R} alone of the semiconductor chip regions 12_{L}, 12_{R} on both sides of the scribe line 14 is tested, the on/off of the switching devices 24_{L}, 24_{R} is made opposite to the on/off of them for testing the semiconductor chip region 12_{L} alone.

As described above, as required, the semiconductor chip regions 12_{L}, 12_{R} on both sides of the scribe line 14 are simultaneously tested, or only one of the semiconductor chip regions 12_{L}, 12_{R} can be tested independently of the other.

As described above, according to the present embodiment, the test device 18 for controlling the tester signal is formed in the scribe line 14 of the semiconductor wafer with the semiconductor chip regions 12 formed on, which can decrease the area of the semiconductor chip region 12. Accordingly, a larger number of semiconductor regions 12 can be formed on the semiconductor wafer 10.

According to the present embodiment, the tester signal can be divided by the test device 18 to be inputted to both the semiconductor chip regions 12_{L}, 12_{R} arranged on both sides of the scribe line 14, whereby a larger number of semiconductor chip regions 12 can be simultaneously tested by the conventional tester without increasing the performance of the tester of the wafer prober. This can much shorten the time required to test a plurality of semiconductor chip regions 12.

According to the present embodiment, the tester signal can be inputted to either of the semiconductor chip regions 12_{L}, 12_{R} arranged on both sides of the scribe line 14, which permits the semiconductor chip regions 12_{L}, 12_{R} to be tested independently of each other. Accordingly, the semiconductor chip region 12 can be judged with high accuracy as to whether it is normal or abnormal, since the semiconductor chip regions 12_{L}, 12_{R} does not electrically influence each other in the test.

According to the present embodiment, the test device 18 formed in the scribe line 14, and the semiconductor chip region 12 are electrically connected by no lines formed on the semiconductor wafer but are electrically connected through the probe card 16, which allows the constitution, arrangement, etc. of the test device 18 to be suitably altered without considering influences on the semiconductor chip region 12. When the semiconductor chip region 12 is cleaved along the scribe line 14 by dicing, no lines are exposed on the cleaved surfaces of the semiconductor chip region 12, and accordingly, the semiconductor chip cleaved in a piece is free from influences, such as the moisture resistance decrease, etc.

(Modifications)

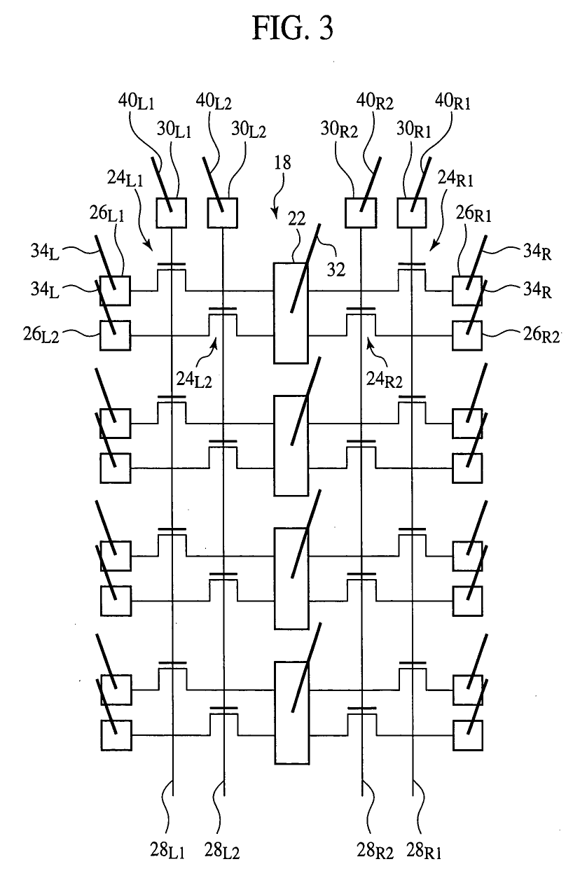

The semiconductor device and the method for testing the same according to a modification of the present embodiment will be explained with reference to FIG. 3. FIG. 3 is a diagrammatic view of the test device of the semiconductor device according to the present modification.

In the above-mentioned first embodiment, the test device 18 has two switching devices 24_{L}, 24_{R} and can divide the tester signal inputted to the pad 22 respectively into two. By increasing the number of the switching devices forming the test device 18, the dividing number of the tester signal can be further increased. In the present modification, a constitution of the test device 18 which can divide the tester signal into four will be explained.

Two pairs of switching devices 24_{L1}, 24_{R1} and switching devices 24_{L2}, 24_{R2} which turning on and off a tester signal to the associated semiconductor chip regions 12 are connected to both sides of each pad 22, to which a tester signal is to be inputted.

The output terminals of the switching devices 24_{L1}, 24_{R1}, 24_{L2}, 24_{R2} are respectively connected to pads 26_{L1}, 26_{R1}, 26_{L2}, 26_{R2} to which the tester signal is to be outputted to.

Signal lines 28_{L1}, 28_{R1}, 28_{L2}, 28_{R2} formed in the scribe line 14, for turning on/off the switching devices 24_{L1}, 24_{R1}, 24_{L2}, 24_{R2} are connected respectively to the switching devices 24_{L1}, 24_{R1}, 24_{L2}, 24_{R2}. The signal lines 28_{L1}, 28_{R1}, 28_{L2}, 28_{R2} are respectively connected to pads 30_{L1}, 30_{R1}, 30_{L2}, 30_{R2} which are formed in the scribe line 14 and to which switch signals for turning on/off the witching devices 24_{L1}, 24_{R1}, 24_{L2}, 24_{R2} are inputted from the probe card 16.

In the test, the probe needles provided on the probe card 16 contact the pads 22, 26_{L1}, 26_{R1}, 26_{L2}, 26_{R2}, 30_{L1}, 30_{R1}, 30_{L2}, 30_{R2} as follows.

The probe needle 32 for inputting a tester signal contacts the pad 22.

The probe needles 34_{L} respectively contact the pads 26_{L1}, 26_{L2}. The pads 26_{L1}, 26_{L2} are electrically connected to the pads 20 in the semiconductor chip region 12_{L} through the probe card 16, i.e., the probe needles 34_{L}, the probe needles 36_{L} which contact the pads 20 in the semiconductor chip region 12_{L}, and the lines 38_{L} electrically interconnecting the probe needles 34_{L}, 36_{L}.

The probe needles 34_{R} respectively contact the pads 26_{R1}, 26_{R2}. The pads 26_{R1}, 26_{R2} are electrically connected to the pads 20 in the semiconductor chip region 12_{R} through the probe card 16, i.e., the probe needles 34_{R}, the probe needles 36_{R} which contact the pads 20 in the semiconductor chip region 12_{R}, and the lines 38_{R} electrically interconnecting the probe needles 34_{R}, 36_{R}.

The probe needles 40_{L1}, 40_{R1}, 40_{L2}, 40_{R2} for inputting switch signals for turning on/off the switching devices 24_{L1}, 24_{R1}, 24_{L2}, 24_{R2} respectively contact pads 30_{L1}, 30_{R1, 30}_{L2}, 30_{R2}.

As described above, by increasing the number of the switching devices forming the test device 18, the dividing number of the tester signal may be increased. In the present modification, the number of the switching devices forming the test device 18 is four to thereby divide the tester signal into four. However, the number of the switching devices can be increased to thereby divide the tester signal into a larger number.

### A Second Embodiment

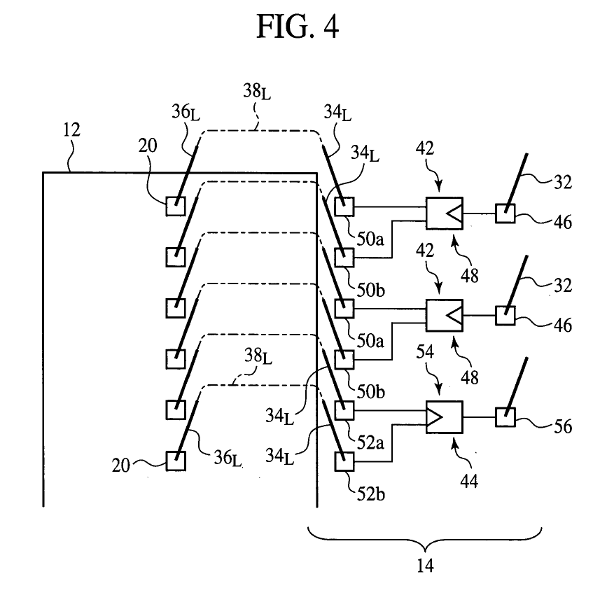

The semiconductor device and the method for testing the same according to a second embodiment of the present invention will be explained with reference to FIG. 4. FIG. 4 is a diagrammatic view of the semiconductor device according to the present embodiment. The same member of the present embodiment as those of the semiconductor device and the method for testing the same according to the first embodiment are represented by the same reference numbers not to repeat or to simplify their explanation.

In the semiconductor device according to the present embodiment, test devices formed in a scribe line 14 includes a test device 42 for dividing a tester signal, and a test device 44 for compressing output signals outputted from a semiconductor chip region 12. The semiconductor device according to the present embodiment will be explained with reference to FIG. 4. FIG. 4 illustrates a semiconductor chip region 12 formed on a semiconductor wafer 10, and a scribe line 14 adjacent to the semiconductor chip region 12.

In the scribe line 14 between the semiconductor chip regions 12, the test device 42 for dividing a tester signal, and the test device 44 for compressing output signals outputted from the semiconductor chip region 12 the tester signal has been inputted are formed. The test devices 42, 44 comprise a semiconductor integrated circuit formed on the semiconductor wafer 10.

The test device 42 includes a pad 46 a tester signal is inputted to, a division circuit 48 for dividing into two the tester signal inputted to the pad 46, and two pads 50a, 50b the divided tester signals are respectively outputted to.

The test device 44 includes two pads 52a, 52b to which output signals outputted from the semiconductor chip region 12 the tester signal has been inputted to are inputted, a compression circuit 54 for compressing the output signals inputted to the pads 52a, 52b, and a pad 56 the compressed output signal is outputted to.

In the test, probe needles provided on a probe card 16 contact the pads 46, 50a, 50b, 52a, 52b, 56 as follows.

The probe needle 32 for inputting tester signal contacts the pad 46.

The probe needles 34_{L} respectively contact the pads 50a, 50b. The pads 50a, 50b are electrically connected to the pads 20 in the semiconductor chip region 12 through the probe card 16, i.e., the probe needles 34_{L}, the probe needles 36_{L} which contact the pads 20 in the semiconductor chip region 12, and the lines 38L electrically interconnecting the probe needles 34_{L}, 36_{L}.

The probe needles 34_{L} respectively contact the pads 52a, 52b. The pads 52a, 52b are electrically connected to the pads 20 in the semiconductor chip region 12 through the probe card 16, i.e., the probe needles 34_{L}, the probe needles 36_{L} which contact the pads 20 in the semiconductor chip region 12, and the lines 38_{L} electrically interconnecting the probe needles 34_{L}, 36_{L}.

The semiconductor device according to the present embodiment is characterized in that the test device 42 for dividing the tester signal, and the test device 44 for compressing the output signals from the semiconductor chip region 12 are formed in the scribe line 14.

In comparison with the case that a tester signal is not divided to be inputted as it is to the semiconductor chip regions 12, the tester signal is divided by the test device 42 to be inputted to the semiconductor chip regions 12, whereby a larger number of the semiconductor chip regions 12 can be simultaneously tested by using the conventional tester without increasing the performance of the tester. Thus, the test on the semiconductor device can be efficient.

The test devices 42, 44 are formed not in the semiconductor chip region 12 but in the scribe line 14, which allows the area of the semiconductor chip region 12 to be smaller. Accordingly, a larger number of semiconductor chip regions 12 can be formed on the semiconductor wafer 10.

The semiconductor device according to the present embodiment is characterized in that the test devices 42, 44 formed in the scribe line 14, and the semiconductor chip region 12 are connected to each other by no line formed on the semiconductor wafer 10 but are electrically connected to each other by the probe card 16.

As described above, the test devices 42, 44, and the semiconductor chip region 12 are physically and electrically separated from each other on the semiconductor wafer 10, which allows the constitution, arrangement, etc. of the test devices 42, 44 to be suitably altered without considering influences on the semiconductor chip region 12.

No lines for electrically connecting the test devices 42, 44 and the semiconductor chip region 12 to each other are present on the semiconductor wafer 10. Accordingly, when the semiconductor chip region 12 is cleaved along the scribe line 14 by dicing into a piece, no lines are exposed on the cleaved surfaces of the semiconductor chip regions 12. Thus, the test devices 42, 44 are formed in the scribe line 14, whereby the cleaved semiconductor chip is free from influences, such as the moisture resistance decrease, etc.

### Modified Embodiments

The present invention is not limited to the above-described embodiments and can cover other various modifications.

For example, in the first embodiment described above, the switching device is formed of MIS transistor. The switching device may comprise any other semiconductor device other than MIS transistor.

In the first embodiment, the test device 18 includes the switching devices 24_{L}, 24_{R}. However, the switching devices 24_{L}, 24_{R} may be omitted for the case that the semiconductor chip regions 12_{L}, 12_{R} are tested simultaneously only.

In the above-described embodiments, the test devices 18, 42, 44 and the semiconductor chip region 12 are physically and electrically separated from each other on the semiconductor wafer 10, and in the test, both are electrically connected to each other through the lines 38_{L}, 38_{R} provided on the probe card 16. However, the test devices 18, 42, 44 and the semiconductor chip region 12 are electrically connected to each other not essentially by the lines 38_{L}, 38_{R} provided on the probe card 16. The test devices 18, 42, 44 and the semiconductor chip region 12 can be electrically connected to each other by various outside lines provided outside the semiconductor wafer 10.

What is claimed is:

1. A semiconductor device comprising:
a semiconductor chip region formed on a semiconductor wafer and including a semiconductor integrated circuit;
a scribe region arranged adjacent to the semiconductor chip region; and
a test device formed in the scribe region, electrically separated from the semiconductor integrated circuit, for controlling a test signal inputted in testing the semiconductor integrated circuit.

2. A semiconductor device comprising:
a first semiconductor chip region formed on a semiconductor wafer and including a semiconductor integrated circuit;
a second semiconductor chip region formed on the semiconductor wafer and including a semiconductor integrated circuit;
a scribe region arranged between the first semiconductor chip region and the second semiconductor chip region; and
a test device formed in the scribe region, electrically separated from the semiconductor integrated circuit in the first semiconductor chip region and the semiconductor integrated circuit in the second semiconductor chip region, for controlling a test signal inputted in testing the semiconductor integrated circuit in the first semiconductor chip region and the semiconductor integrated circuit in the second semiconductor chip region.

3. A semiconductor device according to claim 2, wherein
the test device includes a first pad for the test signal to be inputted to, a second pad for the test signal to be outputted from, and a third pad for the test signal to be outputted from,
the first semiconductor chip region has a fourth pad for the test signal to be inputted to,
the second semiconductor chip region has a fifth pad for the test signal to be inputted to, and
the second pad and the fourth pad are electrically connected to each other via a first line provided in a probe card used in testing the semiconductor integrated circuit, and the third pad and the fifth pad are electrically connected to each other via a second line provided in the probe card.

4. A semiconductor device according to claim 2, wherein
the test device includes a first switching device for turning on/off an input of the test signal to the semiconductor integrated circuit in the first semiconductor chip region, and a second switching device for turning on/off an input of the test signal to the semiconductor integrated circuit in the second semiconductor chip region.

5. A semiconductor device according to claim 3, wherein
the test device includes a first switching device for turning on/off an input of the test signal to the semiconductor integrated circuit in the first semiconductor chip region, and a second switching device for turning on/off an input of the test signal to the semiconductor integrated circuit in the second semiconductor chip region.

6. A semiconductor device according to claim 4, further comprising:
a first signal line which is formed in the scribe region and electrically connected to the first switching device, and to which a first signal for controlling the on/off of the first switching device is inputted; and
a second signal line which is formed in the scribe region and electrically connected to the second switching device, and to which a second signal for controlling the on/off of the second switching device is inputted.

7. A semiconductor device according to claim 5, further comprising:
a first signal line which is formed in the scribe region and electrically connected to the first switching device, and to which a first signal for controlling the on/off of the first switching device is inputted; and
a second signal line which is formed in the scribe region and electrically connected to the second switching device, and to which a second signal for controlling the on/off of the second switching device is inputted.

8. A semiconductor device comprising:
a semiconductor chip region formed on a semiconductor wafer and including a semiconductor integrated circuit;
a scribe region arranged adjacent to the semiconductor chip region;
a test device for signal division formed in the scribe region, electrically separated from the semiconductor integrated circuit, for dividing a test signal inputted in testing the semiconductor integrated circuit; and
a test device for signal compression formed in the scribe region, electrically separated from the semiconductor integrated circuit, for compressing output signals outputted from the semiconductor integrated circuit the test signal has been inputted to.

9. A semiconductor device according to claim 1, wherein
the test device comprises a semiconductor integrated circuit formed on the semiconductor wafer.

10. A semiconductor device according to claim 2, wherein
the test device comprises a semiconductor integrated circuit formed on the semiconductor wafer.

11. A semiconductor device according to claim 8, wherein
the test device comprises a semiconductor integrated circuit formed on the semiconductor wafer.

12. A method for testing a semiconductor device comprising: a semiconductor chip region formed on a semiconductor wafer and including a semiconductor integrated circuit; a scribe region arranged adjacent to the semiconductor chip region; and a test device formed in the scribe region, electrically separated from the semiconductor integrated circuit, for controlling a test signal inputted in testing the semiconductor integrated circuit,
the semiconductor integrated circuit and the test device being electrically connected to each other via an outside line, and
the semiconductor integrated circuit being tested by using the test signal inputted from the test device to the semiconductor integrated circuit via the outside line.

13. A method for testing a semiconductor device comprising: a first semiconductor chip region formed on a semiconductor wafer and including a semiconductor integrated circuit; a second semiconductor chip region formed on the semiconductor wafer and including a semiconductor integrated circuit; a scribe region arranged between the first semiconductor chip region and the second semiconductor chip region; and a test device formed in the scribe region, electrically separated from the semiconductor integrated circuit in the first semiconductor chip region and the semiconductor integrated circuit in the second semiconductor chip region, for controlling a test signal inputted in testing the semiconductor integrated circuit in the first semiconductor chip region and the semiconductor integrated circuit in the second semiconductor chip region,
the semiconductor integrated circuit in the first semiconductor chip and the test device being electrically connected to each other, and the semiconductor integrated circuit in the second semiconductor chip and the test device being electrically connected to each other, and
the semiconductor integrated circuit in the first semiconductor chip region and the semiconductor integrated circuit in the second semiconductor chip region being tested by using the test signal inputted from the test device to the semiconductor integrated circuit in the first semiconductor chip region and the semiconductor integrated circuit in the second semiconductor chip region.

14. A method for testing a semiconductor device according to claim 13, wherein
the test device includes a first pad for the test signal to be inputted to, a second pad for the test signal to be outputted from, and a third pad for the test signal to be outputted from,
the first semiconductor chip region has a fourth pad for the test signal to be inputted to,
the second semiconductor chip region has a fifth pad for the test signal to be inputted to,
the second pad and the fourth pad are electrically connected to each other via a first line provided in a probe card used in testing the semiconductor integrated circuit, and the third pad and the fifth pad are electrically connected to each other via a second line provided in the probe card,
the test signal is inputted to the first pad of the test device via the probe card,
the test signal outputted from the second pad is inputted to the semiconductor integrated circuit in the first semiconductor chip region via the first line, and
the test signal outputted from the third pad is inputted to the semiconductor integrated circuit in the second semiconductor chip region via the second line.

15. A method for testing a semiconductor device according to claim 13, wherein
the test device includes a first switching device for turning on/off an input of the test signal to the semiconductor integrated circuit in the first semiconductor chip region, and a second switching device for turning on/off an input of the test signal to the semiconductor integrated circuit in the second semiconductor chip region, and
the on/off of the first switching device and the second switching device is controlled to thereby input the test signal simultaneously to the semiconductor integrated circuit in the first semiconductor chip region and the semiconductor integrated circuit in the second semiconductor chip region.

16. A method for testing a semiconductor device according to claim 14, wherein
the test device includes a first switching device for turning on/off an input of the test signal to the semiconductor integrated circuit in the first semiconductor chip region, and a second switching device for turning on/off an input of the test signal to the semiconductor integrated circuit in the second semiconductor chip region, and
the on/off of the first switching device and the second switching device is controlled to thereby input the test signal simultaneously to the semiconductor integrated circuit in the first semiconductor chip region and the semiconductor integrated circuit in the second semiconductor chip region.

17. A method for testing a semiconductor device according to claim 13, wherein
the test device includes a first switching device for turning on/off an input of the test signal to the semiconductor integrated circuit in the first semiconductor chip region, and a second switching device for turning on/off an input of the test signal to the semiconductor integrated circuit in the second semiconductor chip region, and
the on/off of the first switching device and the second switching device is controlled to thereby input the test signal to either of the semiconductor integrated circuit in the first semiconductor chip region and the semiconductor integrated circuit in the second semiconductor chip region.

18. A method for testing a semiconductor device according to claim 14, wherein
the test device includes a first switching device for turning on/off an input of the test signal to the semiconductor integrated circuit in the first semiconductor chip region, and a second switching device for turning on/off an input of the test signal to the semiconductor integrated circuit in the second semiconductor chip region, and
the on/off of the first switching device and the second switching device is controlled to thereby input the test signal to either of the semiconductor integrated circuit in the first semiconductor chip region and the semiconductor integrated circuit in the second semiconductor chip region.
